(19) United States
(12) Patent Application Publication
(10) Pub. No.: US 2026/0149264 A1
(43) Pub. Date: May 28, 2026

(54) SEMICONDUCTOR DEVICE

(71) Applicant: Renesas Electronics Corporation, Tokyo (JP)

(72) Inventor: Hideyuki TAJIMA, Tokyo (JP)

(21) Appl. No.: 19/364,092

(22) Filed: Oct. 21, 2025

(30) Foreign Application Priority Data
Nov. 26, 2024 (JP) 2024-205459

(51) Int. Cl. H02H 9/02; G01R 19/165; H02H 1/00

(52) U.S. Cl. CPC H02H 9/02; G01R 19/16504; H02H 1/0007

(57) ABSTRACT

A semiconductor device includes a power device, a booster circuit, and an overcurrent detection circuit. The overcurrent detection circuit includes a sense circuit that outputs a voltage corresponding to a current flowing in the power device, and a detection current generation circuit that generates a detection current depending on an output from the sense circuit. The detection current generation circuit includes a first control circuit that operates with a boosted voltage from the booster circuit and controls a first current circuit depending on the voltage output from the sense circuit, and a second control circuit that operates with a power source voltage and controls a second current circuit depending on the voltage output from the sense circuit.

### CROSS-REFERENCE TO RELATED APPLICATIONS

The disclosure of Japanese Patent Application No. 2024-205459 filed on Nov. 26, 2024 including the specification, drawings and abstract is incorporated herein by reference in its entirety.

### BACKGROUND

The present invention relates to a semiconductor device, for example, a semiconductor device including an overcurrent detection circuit that detects overcurrent flowing in a power device.

There is disclosed a technique listed below.

[Patent Document 1] Japanese Unexamined Patent Application Publication No. 2019-212930

For example, Patent Document 1 discloses a semiconductor device including an overcurrent detection circuit that detects overcurrent flowing in a power device (for example, a power transistor).

For example, paragraph number [0031] and FIG. 1 of Patent Document 1 describe that a boosted voltage generated by a charge pump circuit is supplied to the overcurrent detection circuit (an overcurrent protection circuit in Patent Document 1). The overcurrent protection circuit performs operation of detecting overcurrent with the boosted voltage.

### SUMMARY

As will be described in detail below with reference to Comparative Examples, the present inventor has found that, when an overcurrent detection circuit is operated by using multiple boosted voltages generated by respective booster circuits such as a charge pump circuit, current consumption of the booster circuits increases and an occupied area of the booster circuits in a semiconductor device increases, thereby leading to increase in manufacturing costs.

An overview of a representative embodiment of embodiments disclosed in the present application will be briefly described as follows.

Namely, a semiconductor device according to one embodiment includes a power device, a booster circuit, and an overcurrent detection circuit. The overcurrent detection circuit includes a sense circuit that outputs a voltage corresponding to a current flowing in the power device, and a detection current generation circuit that generates a detection current depending on an output from the sense circuit. Here, the detection current generation circuit includes a first current source that causes a first current to flow from a detection output node of the detection current generation circuit, a first current circuit that supplies a second current higher than the first current to the detection output node, and a second current circuit that supplies a third current having a value larger than the first current. In addition, the detection current generation circuit includes a limiting circuit that is connected between the second current circuit and the detection output node and limits a voltage at the detection output node. Further, the detection current generation circuit includes a first control circuit that operates with a boosted voltage from the booster circuit and controls the first current circuit depending on the voltage output from the sense circuit, and a second control circuit that operates with a power source voltage and controls the second current circuit depending on the voltage output from the sense circuit.

Other problems and novel features will be clarified from the description of this specification and the accompanying drawings.

According to one embodiment, it is possible to provide a semiconductor device capable of reducing manufacturing costs.

### BRIEF DESCRIPTION OF THE DRAWINGS

FIG. 1 is a block diagram illustrating a configuration of a semiconductor device according to a first embodiment.

FIG. 2 is a block diagram illustrating a configuration of a detection current generation circuit according to the first embodiment.

FIG. 3 is a circuit diagram illustrating a configuration of the detection current generation circuit according to the first embodiment.

FIG. 4 is a cross-sectional view illustrating a cross section of a semiconductor chip according to the first embodiment.

FIG. 5 is a diagram for describing operation of the detection current generation circuit according to the first embodiment.

FIG. 6 is a diagram for describing the operation of the detection current generation circuit according to the first embodiment.

FIG. 7 is a diagram for describing the operation of the detection current generation circuit according to the first embodiment.

FIG. 8 is a circuit diagram illustrating a configuration of a detection current generation circuit according to a second embodiment.

FIG. 9 is a circuit diagram illustrating a configuration of an overcurrent detection circuit according to Comparative Example 1.

FIGS. 10A and 10B are diagrams for describing a level shift circuit according to Comparative Example 1.

FIG. 11 is a graph for describing overcurrent detection according to Comparative Example 2.

FIGS. 12A and 12B are diagrams illustrating a configuration of an overcurrent detection circuit according to Comparative Example 3.

FIGS. 13A and 13B are waveform diagrams for describing operations of Comparative Example 3.

FIGS. 14A and 14B are diagrams for describing a problem of Comparative Example 3.

FIGS. 15A and 15B are diagrams for describing a problem of Comparative Example 3.

FIGS. 16A and 16B are diagrams for describing a problem of Comparative Example 3.

### DETAILED DESCRIPTION

Hereinafter, embodiments of the present invention will be described with reference to the drawings. Note that the disclosure is merely an example, and appropriate modifications that can be easily conceived by those skilled in the art while maintaining the gist of the invention are naturally included in the scope of the present invention.

In addition, in this specification and all the drawings, the same reference signs are assigned to the same elements as those described previously in the previous drawings, and the detailed description thereof may be omitted as appropriate.

### Comparative Examples

Before the present invention is described, it has been found as a result of studies by the present inventor that, when an overcurrent detection circuit is operated by using multiple boosted voltages generated by respective charge pump circuits, a problem arises in that current consumption of the overcurrent detection circuit increases and an occupied area thereof increases. Therefore, it has been found that it is desirable to reduce the use of the boosted voltages and operate the overcurrent detection circuit with voltages (power source voltages) supplied from the outside of the semiconductor device if possible. Therefore, the present inventor developed overcurrent detection circuits that can be operated with a voltage supplied from the outside if possible, but it has been found that the developed overcurrent detection circuits have a new problem. Hereinafter, three types of developed overcurrent detection circuits will be described as comparative examples.

### Comparative Examples 1

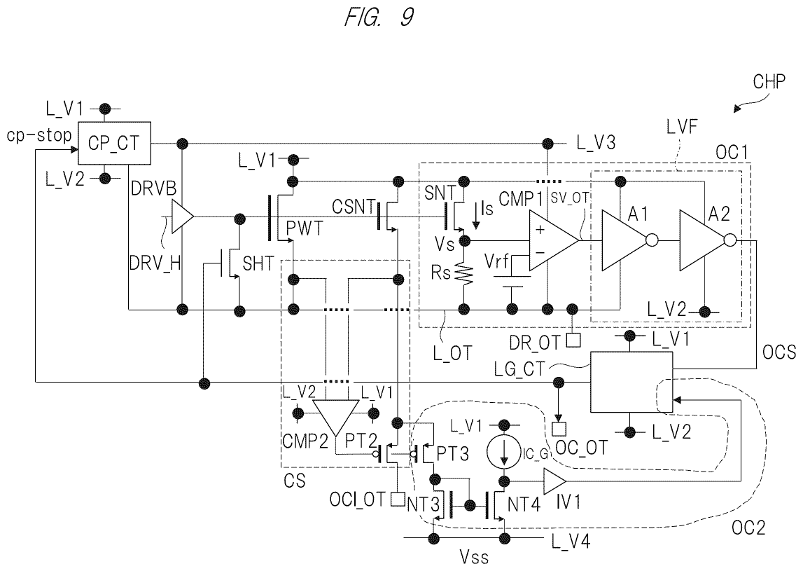

FIG. 9 is a circuit diagram illustrating a configuration of an overcurrent detection circuit according to Comparative Example 1. In FIG. 9, CHP represents a semiconductor device including the overcurrent detection circuit, and DR_OT represents an output terminal of the semiconductor device CHP. In addition, in FIG. 9, OC_OT represents a detection output terminal of the semiconductor device CHP, and OCI_OT represents a detection current terminal of the semiconductor device CHP. A load (not illustrated) is connected to the output terminal DR_OT of the semiconductor device CHP, and the load is driven in response to an output signal from the output terminal DR_OT. For example, a high level output signal is supplied from a high-side drive circuit to the output terminal DR_OT, and a low level output signal is supplied from a low-side drive circuit to drive the load.

In FIG. 9, the low-side drive circuit is omitted, and only the high-side drive circuit is illustrated. The high-side drive circuit includes an N-channel type field-effect transistor (hereinafter also referred to as an N-type transistor) PWT which is a power device, a shutdown N-type transistor SHT, a driving buffer DRVB, a charge pump circuit CP_CT which is a booster circuit, a first overcurrent detection circuit OC1, and a logic circuit LG_CT. In FIG. 9, in addition to these circuits, a current sensing N-type transistor CSNT, a current detection circuit CS, and a second overcurrent detection circuit OC2 are illustrated and will be described in Comparative Example 2, and descriptions thereof will be omitted here.

The charge pump circuit CP_CT is connected to a first voltage wiring (a first power supply wiring) L_V1, a second voltage wiring (a second power supply wiring) L_V2, a third voltage wiring (a third power supply wiring) L_V3, and an output wiring L_OT connected to the output terminal DR_OT. A voltage (a first voltage) VCC having a predetermined value is supplied to the first voltage wiring L_V1, and a voltage (a second voltage) VCCm having a value lower than the voltage VCC by a predetermined value (for example, 6 V) is supplied to the second voltage wiring L_V2. Here, the first voltage VCC is a power source voltage supplied from the outside of the semiconductor device CHP, and the second voltage VCCm is a power source voltage generated from the first voltage VCC inside the semiconductor device CHP.

Operation of the charge pump circuit CP_CT is controlled in response to an operation control signal cp-stop. As will be described below, when overcurrent is detected by the first overcurrent detection circuit OC1, the operation control signal cp-stop is set to a high level by the logic circuit (an output circuit) LG_CT, and when overcurrent is not detected, the operation control signal cp-stop is set to a low level by the logic circuit LG_CT.

When the operation control signal cp-stop is set to the low level, the charge pump circuit CP_CT performs boosting operation with the voltage VCC in the first voltage wiring L_V1 and the voltage VCCm in the second voltage wiring L_V2 as power source voltages, adds (superimposes) a predetermined voltage (for example, 6 V) generated by the boosting operation to a voltage in an output wiring L_OT (namely, the output terminal DR_OT), and supplies an obtained voltage to the third voltage wiring L_V3. Namely, when the charge pump circuit CP_CT is operating, the voltage of the third voltage wiring L_V3 becomes the voltage of the output wiring L_OT+6 V. Hereinafter, the voltage of the third voltage wiring L_V3 is also represented by outp6v. Note that, when the operation control signal cp-stop is set to the high level, the charge pump circuit CP_CT stops the boosting operation.

A drain-source path of the N-type transistor PWT is connected in series between the first voltage wiring L_V1 and the output wiring L_OT, and a gate thereof is connected to an output of the driving buffer DRVB. The driving buffer DRVB is connected to the third voltage wiring L_V3 and the output wiring L_OT, operates with the voltage outp6v of the third voltage wiring L_V3 and the voltage of the output wiring L_OT as power source voltages, supplies a supplied high-side drive signal DRV_H to the gate of the N-type transistor PWT, and controls the N-type transistor PWT to be brought into a conductive state or a non-conductive state. The N-type transistor PWT has a large size, supplies a large drive current (a drain-source current) from the first voltage wiring L_V1 to the output wiring L_OT and the output terminal DR_OT in the case of the conductive state, and supplies the large drive current to a load (not illustrated).

A drain-source path of the shutdown N-type transistor SHT is connected in series between the gate of the N-type transistor PWT and the output wiring L_OT, and the operation control signal cp-stop is supplied to the gate. When no overcurrent is detected, the shutdown N-type transistor SHT is brought into the non-conductive state in response to a low-level operation control signal cp-stop, and in a case where overcurrent is detected, the shutdown N-type transistor SHT is brought into the conductive state in response to a high-level operation control signal cp-stop. This enables the N-type transistor PWT to be brought into the non-conductive state in the case where the overcurrent is detected, thereby preventing the N-type transistor PWT from being broken.

### Configuration of First Overcurrent Detection Circuit

The first overcurrent detection circuit OC1 includes an N-type transistor SNT which is a sense device, a sense resistor Rs, a reference voltage Vrf, a first comparison circuit CMP1, and a level shift circuit LVF.

A drain of the N-type transistor SNT is connected to the first voltage wiring L_V1, a source thereof is connected to the output wiring L_OT via the sense resistor Rs, and a gate thereof is connected to the gate of the N-type transistor PWT. A positive input (+) of the first comparison circuit CMP1 is connected to a connection node connecting the source of the N-type transistor SNT and the sense resistor Rs, and a negative input (−) thereof is connected to the output wiring L_OT via the reference voltage Vrf. In addition, the first comparison circuit CMP1 is connected to the third voltage wiring L_V3 and the output wiring L_OT and performs comparison operation with the voltage outp6v of the third voltage wiring L_V3 and the voltage of the output wiring L_OT as power source voltages.

Here, the size of the N-type transistor SNT is 1 /K1 (hereinafter K 1 also represents a size ratio) with respect to the size of the N-type transistor PWT. This indicates that, when both the N-type transistors PWT and SNT are brought into the conductive state by the driving buffer DRVB, a value of a current (a sense current) Is flowing in a drain-source path of the N-type transistor SNT becomes a small value that is 1 /K1 times the value of the current flowing in the drain-source path of the N-type transistor PWT. The first comparison circuit CMP1 compares a sense voltage Vs generated in the sense resistor Rs due to the sense current Is with the reference voltage Vrf and outputs a comparison result to the level shift circuit LVF in response to a sense output signal SV_OT which changes between the voltage outp6v of the third voltage wiring L_V3 and the voltage of the output wiring L_OT.

The level shift circuit LVF includes two amplifier circuits A1 and A2. The amplifier circuit A1 is connected to the first voltage wiring L_V1 and the output wiring L_OT and amplifies the sense output signal SV_OT with the voltage VCC of the first voltage wiring L_V1 and the voltage of the output wiring L_OT as power source voltages. The amplifier circuit A2 amplifies an output signal from the amplifier circuit A1 with the voltage VCC of the first voltage wiring L_V1 and the voltage VCCm of the second voltage wiring L_V2 as power source voltages. This causes the sense output signal SV_OT that changes between the voltage outp6v and the voltage of the output wiring L_OT to be level-shifted to a detection signal OCS that changes between the voltage VCC and the voltage VCCm.

The detection signal OCS is supplied to the logic circuit LG_CT. The logic circuit LG_CT is connected to the first voltage wiring L_V1 and the second voltage wiring L_V2 and operates with the voltage VCC and the voltage VCCm as power source voltages. Although not particularly limited, the logic circuit LG_CT generates a high-level detection output signal when the detection signal OCS is set to the high level (the voltage VCC), and generates a low-level detection output signal in a case where the detection signal OCS is set to the low level (the voltage VCCm). The generated detection output signal is output to the outside of the semiconductor device CHP via the detection output terminal OC_OT and simultaneously is supplied as the operation control signal cp-stop to the charge pump circuit CP_CT and the gate of the shutdown N-type transistor SHT.

<<<Problem of Comparative Example 1>>

The voltage of the output wiring L_OT changes between the vicinity of the voltage VCC and the vicinity of a ground voltage (not illustrated) due to conduction/non-conduction of the N-type transistor PWT in the high-side drive circuit and an N-type transistor (not illustrated) which is a power device in the low-side drive circuit. In a case where the voltage of the output wiring L_OT is in the vicinity of the voltage VCC, a potential difference between the voltage of the output wiring L_OT and the voltage VCC of the first voltage wiring L_V1 supplied as the power source voltage to the level shift circuit LVF becomes small, operation of the level shift circuit LVF becomes indeterminate or unstable, and the sense output signal SV_OT is not accurately transmitted to the logic circuit LG_CT.

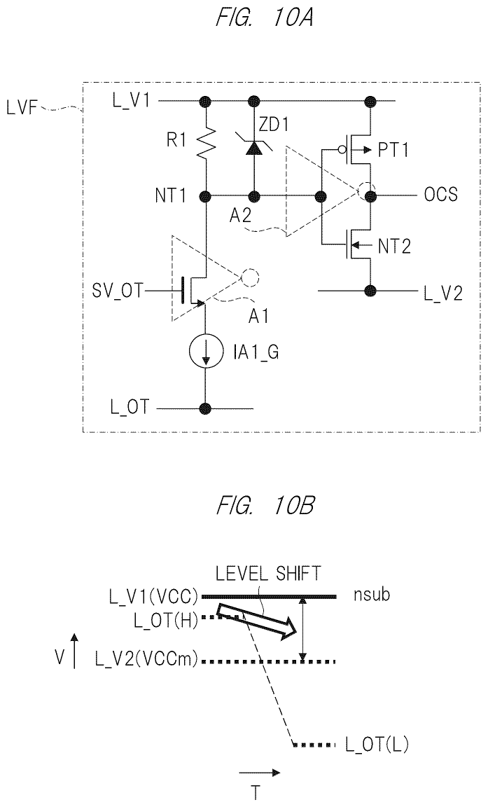

Next, an example of the level shift circuit LVF will be described with reference to the drawings. FIGS. 10A and 10B are diagrams for describing a level shift circuit according to Comparative Example 1. FIG. 10A is a circuit diagram illustrating a configuration of the level shift circuit LVF, and FIG. 10B is a waveform diagram illustrating operation of the level shift circuit LVF.

As illustrated in FIG. 10A, the level shift circuit LVF includes N-type transistors NT1 and NT2, a P-channel type field-effect transistor (hereinafter also referred to as a P-type transistor) PT1, a resistor R1, a Zener diode ZD1, and a current source IA1_G. A drain-source path of the N-type transistor NT1, the resistor R1, and the current source IA1_G are connected in series between the first voltage wiring L_V1 and the output wiring L_OT, and the sense output signal SV_OT is supplied to a gate of the N-type transistor NT1. This makes an inverter circuit corresponding to the amplifier circuit A1 include the N-type transistor NT1, the resistor R1, and the current source IA1_G. A signal obtained by performing phase inversion of the sense output signal SV_OT is output from a connection node between a drain of the N-type transistor NT1 and the resistor R1 and is supplied to the amplifier circuit A2. The amplifier circuit A2 includes an inverter circuit including the N-type transistor NT2 and the P-type transistor PT1 connected in series between the first voltage wiring L_V1 and the second voltage wiring L_V2. The amplifier circuit A2 performs phase inversion of an output from the amplifier circuit A1 and outputs the phase-inverted output as the detection signal OCS. Note that the Zener diode ZD1 clamps an input voltage of the amplifier circuit A2 to a predetermined value.

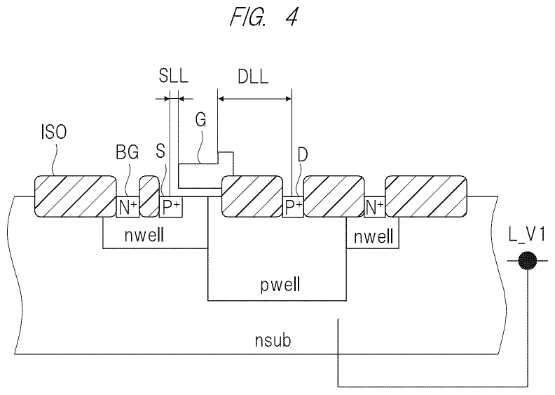

In FIG. 10B, the vertical axis represents a voltage V, and the horizontal axis represents a time T. In FIG. 10B, L_V1(VCC) represents the voltage VCC of the first voltage wiring L_V1. In addition, in FIG. 10B, L_V2(VCCm) represents the voltage VCCm of the second voltage wiring L_V2. Further, in FIG. 10B, L_OT(H) and L_OT(L) represent voltages of the output wiring L_OT. Here, L_OT(H) represents the voltage of the output wiring L_OT when the power device in the high-side drive circuit is brought into the conductive state, and L_OT(L) represents the voltage of the output wiring L_OT when the power device in the low-side drive circuit is brought into the conductive state. Note that reference sign nsub will be described below in FIG. 4, and thus the description thereof will be omitted here.

The level shift circuit LVF operates to convert (perform level shift of) the signal (the sense output signal SV_OT) which changes between the voltage L_V1(VCC) and the voltage L_OT(H) into the signal (the detection signal OCS) which changes between the voltage L_V1(VCC) and the voltage L_V2(VCCm). However, as illustrated in FIG. 10B, when the voltage of the output wiring L_OT becomes the voltage L_OT(H), a potential difference between the voltage VCC of the first voltage wiring L_V1 supplied to the amplifier circuit A1 and the voltage L_OT(H) of the output wiring L_OT collapses and is reduced. As a result, even when the sense output signal SV_OT supplied to the amplifier circuit A1 is set to the high level, it is difficult for the amplifier circuit A1 to transmit the signal set to the low level to the amplifier circuit A2.

Namely, according to the first overcurrent detection circuit OC1 of Comparative Example 1, a supply destination of a boosted voltage generated by the charge pump circuit CP_CT can be limited to the first comparison circuit CMP1 (FIG. 9), but a new problem arises in that it is difficult to transmit a sense signal.

<<Comparative Example 2>>

Since Comparative Example 1 has the above-described problem, the present inventor developed an overcurrent detection circuit according to Comparative Example 2 which additionally includes the current sensing N-type transistor CSNT, the current detection circuit CS, and the second overcurrent detection circuit OC2 as illustrated in FIG. 9.

A drain of the current sensing N-type transistor CSNT is connected to the first voltage wiring L_V1, a source thereof is connected to the current detection circuit CS, and a gate thereof is connected to the gate of the N-type transistor PWT. In addition, similarly to the N-type transistor SNT which is a sense device, the size of the current sensing N-type transistor CSNT is 1/K2 (hereinafter K2 also represents a size ratio) with respect to the size of the N-type transistor PWT. This indicates that, when both the N-type transistors PWT and CSNT are brought into the conductive state by the driving buffer DRVB, a value of a current (a detection current) flowing in a drain-source path of the N-type transistor CSNT becomes a small value that is 1/K2 times the value of the current flowing in the drain-source path of the N-type transistor PWT. Note that the size ratio K2 may be the same value as or different from the size ratio K1.

The current detection circuit CS includes a second comparison circuit CMP2 and a P-type transistor PT2. A source of the P-type transistor PT2 is connected to the drain of the current sensing N-type transistor CSNT, and a drain thereof is connected to a detection current terminal OCI_OT. A pair of input terminals of the second comparison circuit CMP2 are connected to the source of the N-type transistor PWT and the source of the current sensing N-type transistor CSNT, and an output terminal thereof is connected to the gate of the P-type transistor PT2. The second comparison circuit CMP2 operates with the voltage VCC in the first voltage wiring L_V1 and the voltage VCCm in the second voltage wiring L_V2 as power source voltages and controls the P-type transistor PT2 so that a current flowing in the P-type transistor PT2 is proportional to the current flowing in the N-type transistor PWT. This enables the value of the current flowing in the N-type transistor PWT to be known by measuring a current of the detection current terminal OCI_OT outside the semiconductor device CHP.

The second overcurrent detection circuit OC2 includes a P-type transistor PT3, N-type transistors NT3 and NT4, a current source IC_G, and an inverter circuit IV1. A source of the P-type transistor PT3 is connected to the source of the P-type transistor PT2, and a gate thereof is connected to the gate of the P-type transistor PT2. In addition, a source of the N-type transistor NT3 is connected to a fourth voltage wiring L_V4, a drain and a gate thereof are connected to the drain of the P-type transistor PT3 and further connected to a gate of the N-type transistor NT4. A drain of the N-type transistor NT4 is connected to the first voltage wiring L_V1 via a current source IC_G and is connected to the logic circuit LG_CT via the inverter circuit IV1. In addition, a source of the N-type transistor NT4 is connected to the fourth voltage wiring L_V4. A ground voltage VSS is supplied to the fourth voltage wiring L_V4 from the outside of the semiconductor device CHP.

The N-type transistors NT3 and NT4 constitute a current mirror circuit, and a current proportional to the current flowing in the P-type transistor PT2, that is, a current flowing in the current sensing N-type transistor CSNT, is supplied to the current mirror circuit via the P-type transistor PT3. A voltage corresponding to a difference between a current generated by the current source IC_G and a current output from the current mirror circuit is input to the inverter circuit IV1. For example, in a case where the current flowing in the current sensing N-type transistor CSNT is higher than the current generated by the current source IC_G, the input to the inverter circuit IV1 is performed at the low level, and a high-level signal is supplied from the inverter circuit IV1 to the logic circuit LG_CT. This causes the logic circuit LG_CT to generate a high-level detection output signal and output the high-level detection output signal to the outside of the semiconductor device CHP via the detection output terminal OC_OT and supply the high-level detection output signal as the operation control signal cp-stop to the charge pump circuit CP_CT and the gate of the shutdown N-type transistor SHT.

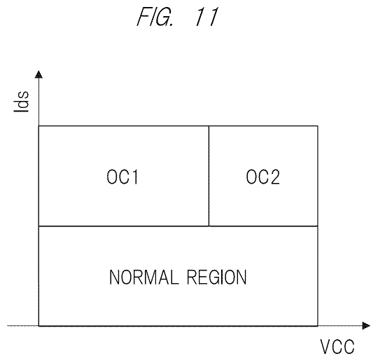

In the configuration of Comparative Example 2, in a case where the voltage in the output wiring L_OT is in the vicinity of the voltage VCC, the overcurrent is detected by the second overcurrent detection circuit OC2, and in a case where the voltage in the output wiring L_OT is in the vicinity of the voltage VCCm, the overcurrent is detected by the first overcurrent detection circuit OC1. FIG. 11 is a graph for describing overcurrent detection according to Comparative Example 2. In FIG. 11, the horizontal axis represents the voltage in the output wiring L_OT, and the voltage increases from left to right. In addition, in FIG. 11, the vertical axis represents a current (drain-source current) Ids flowing in the N-type transistor PWT.

In FIG. 11, a normal region indicates a region in which no overcurrent is detected, a region represented by reference sign OC1 indicates a region in which the overcurrent is detected by the first overcurrent detection circuit OC1, and a region represented by reference sign OC2 indicates a region in which the overcurrent is detected by the second overcurrent detection circuit OC2. Note that the second overcurrent detection circuit OC2 cannot detect the overcurrent in a case where the voltage in output wiring L_OT is lower than the voltage VCCm.

<<<Problems of Comparative Example 2>>>

In Comparative Example 2, since the overcurrent is detected by the two overcurrent detection circuits of the first overcurrent detection circuit OC1 and the second overcurrent detection circuit OC2, it becomes complicated to control the two overcurrent detection circuits. In addition, the current detection circuit CS needs to be provided in a configuration of the second overcurrent detection circuit OC2, and an occupied area thereof increases. Further, in a case where a plurality of drive circuits (a high-side drive circuit and a low-side drive circuit) are provided in the semiconductor device CHP and the semiconductor device has a multi-channel configuration, the second overcurrent detection circuit OC2 can be made common to the plurality of drive circuits. However, since the current detection circuit CS needs to be provided in each of the plurality of drive circuits, the occupied area further increases.

Namely, according to Comparative Example 2, it is possible to solve the problem of Comparative Example 1, but new problems of complicated control and increase in the occupied area arise.

<<Comparative Example 3>>

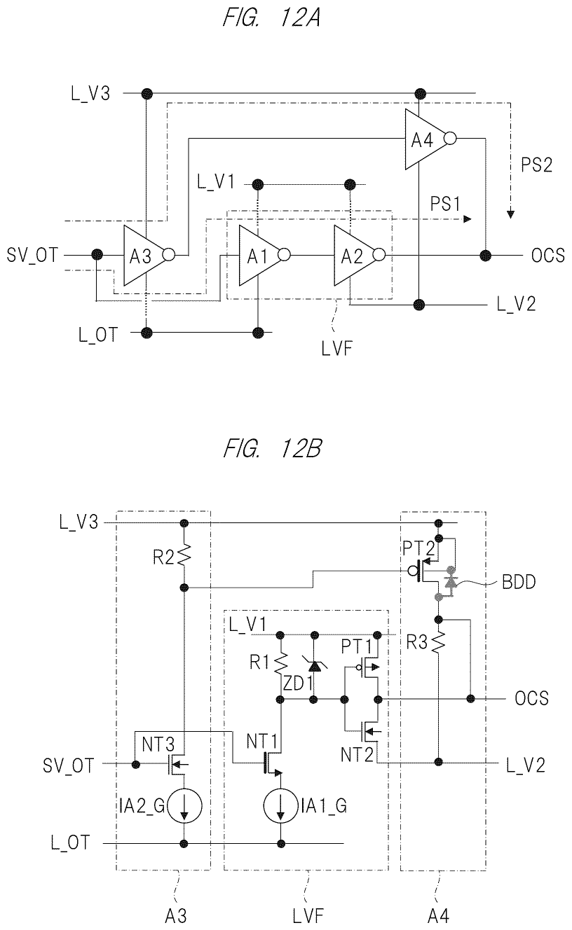

Since Comparative Example 2 also has the problems, the present inventor further studied and developed an overcurrent detection circuit according to Comparative Example 3. FIG. 12 is a diagram illustrating a configuration of the overcurrent detection circuit according to Comparative Example 3. In Comparative Example 3, a portion of the level shift circuit LVF (FIG. 9) described in Comparative Example 1 is changed. In FIG. 12, only the changed portion is illustrated.

In Comparative Example 3, amplifier circuits A3 and A4 that operate with the voltage outp6v generated by the charge pump circuit CP_CT (FIG. 9) and supplied to the third voltage wiring L_V3 as a power source voltage are added to the level shift circuit LVF. Namely, in Comparative Example 3, as illustrated in FIG. 12A, the amplifier circuit A3 that amplifies the sense output signal SV_OT from the first comparison circuit CMP1 (FIG. 9) with the voltage outp6v in the third voltage wiring L_V3 and the voltage in the output wiring L_OT as the power source voltages is added. Further, as illustrated in FIG. 12A, the amplifier circuit A4 that amplifies an output signal from the amplifier circuit A3 with the voltage outp6v in the third voltage wiring L_V3 and the voltage VCCm in the second voltage wiring L_V2 as the power source voltages is added. In addition, an output of the amplifier circuit A4 is connected to and combined with an output of the level shift circuit LVF to become the detection signal OCS. A configuration of the level shift circuit LVF is similar to that described with reference to FIG. 10.

In other words, in Comparative Example 3, as paths through which the sense output signal SV_OT is transmitted, a first signal path PS1 through the amplifier circuits A1 and A2 constituting the level shift circuit LVF and a second signal path (a signal path through the amplifier circuits A3 and A4) PS2 connected to the signal path PS1 in parallel are added, and an output of the signal path PS1 and an output of the signal path PS2 are combined. This enables transmission at the low level to be performed at the output of the amplifier circuit A3 when the power source voltage of the amplifier circuit A1 collapses and the output of the amplifier circuit A1 is not set to the low level.

FIG. 12B illustrates a specific example of the block diagram illustrated in FIG. 12A. The amplifier circuit A3 includes a resistor R2, the N-type transistor NT3, and a current source IA2_G which are connected in series between the third voltage wiring L_V3 and the output wiring L_OT. The sense output signal SV_OT is supplied to a gate of the N-type transistor NT3, and an output signal of the amplifier circuit A3 is taken out from a connection node between the resistor R2 and the N-type transistor NT3.

The amplifier circuit A4 includes the P-type transistor PT2 and a resistor R3 which are connected in series between the third voltage wiring L_V3 and the second voltage wiring L_V2. In FIG. 12B, reference sign BDD represents a body diode formed between the drain and a back gate of the P-type transistor PT2. The output signal from the amplifier circuit A3 is supplied to the gate of the P-type transistor PT2, and an output signal of the amplifier circuit A4 is taken out from a connection node between the resistor R3 and the drain of the P-type transistor PT2.

Similarly to the amplifier circuits A1 and A2, the amplifier circuits A3 and A4 also output phase-inverted output signals with respect to the signals supplied to the gates of the transistors and thus can be regarded as inverter circuits. Note that, since the level shift circuit LVF has been described with reference to FIG. 10, the description thereof will be omitted.

<<<Operation of Comparative Example 3>>>

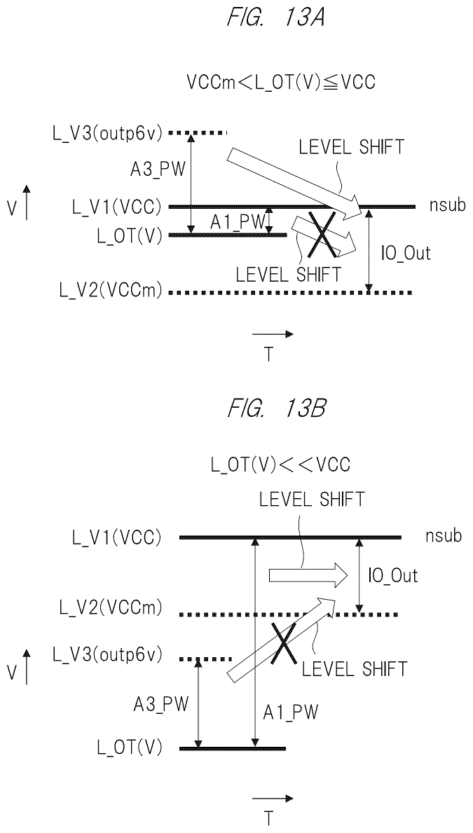

FIGS. 13A and 13B are waveform diagrams for describing operations of Comparative Example 3. The operations of Comparative Example 3 illustrated in FIGS. 12A and 12B change depending on the voltage of the output wiring L_OT. FIG. 13A illustrates the operation in a case where the voltage of the output wiring L_OT is equal to or lower than the voltage VCC of the first voltage wiring L_V1 and exceeds the voltage VCCm of the second voltage wiring L_V2 (VCCm <L_OT(V) ≤VCC). On the other hand, FIG. 13B illustrates the operation in a case where the voltage in the output wiring L_OT is very much lower than the voltage VCC in the first voltage wiring L_V1 (L_OT(V) <<VCC).

In FIGS. 13A and 13B, the horizontal axis T represents time, and the vertical axis V represents voltage. The time progresses in a direction of an arrow illustrated on the horizontal axis, and the voltage increases in a direction of an arrow illustrated on the vertical axis. In addition, in FIGS. 13A and 13B, L_V3(V) represents the voltage of the third voltage wiring L_V3, and L_OT(V) represents the voltage of the output wiring L_OT. Similarly, in FIGS. 13A and 13B, L_V1(VCC) represents the voltage of the first voltage wiring L_V1, and L_V2(VCCm) represents the voltage of the second voltage wiring L_V2.

As illustrated in FIG. 13A, in a case where the voltage L_OT(V) of the output wiring L_OT is equal to or lower than the voltage L_V1(VCC) of the first voltage wiring L_V1, that is, in a case where the voltage L_OT(V) is approximate to the voltage VCC, a power source voltage A1_PW of the amplifier circuit A1 which is a potential difference between the first voltage wiring L_V1 and the output wiring L_OT is reduced (collapses). Therefore, the level shift is not performed by the amplifier circuits A1 and A2.

At this time, the voltage L_OT(V) of the output wiring L_OT is higher than the voltage L_V2(VCCm) of the second voltage wiring L_V2, and the voltage L_V3(outp6v) of the third voltage wiring L_V3 becomes much higher than the voltage L_OT(V). Therefore, a power source voltage A3_PW of the amplifier circuit A3 which is a potential difference between the voltage L_V3(outp6v) of the third voltage wiring L_V3 and the voltage L_OT(V) of the output wiring L_OT increases, the level shift by the amplifier circuits A3 and A4 is performed, and for example, an output IO_Out that changes between the voltage L_V1(VCC) and the voltage L_V2(VCCm) is output from the amplifier circuit A4.

On the other hand, in FIG. 13B, since the voltage L_OT(V) is very much lower than the voltage L_V1(VCC), whereby the voltage L_V3(outp6v) is also lower than the voltage L_V(VCCm), the level shift is not performed by the amplifier circuits A3 and A4. At this time, since the power source voltage A1_PW of the amplifier circuit A1 increases, the level shift by the amplifier circuits A1 and A2 is performed, and the output IO_Out that changes between the voltage L_V1(VCC) and the voltage L_V2(VCCm) is output from the amplifier circuit A2.

<<<Problems of Comparative Example 3>>>

According to Comparative Example 3, the voltage outp6 v generated by the charge pump circuit CP_CT needs to be supplied to the amplifier circuits A3 and A4, and the amount of current supplied from the charge pump circuit CP_CT to the amplifier circuits A3 and A4 can be reduced to be small. Further, the current detection circuit CS and the second overcurrent detection circuit OC2 (FIG. 9) described in Comparative Example 2 can be made unnecessary. Therefore, it is possible to reduce the complicated control and the increase in the occupied area which are the problems of Comparative Example 2.

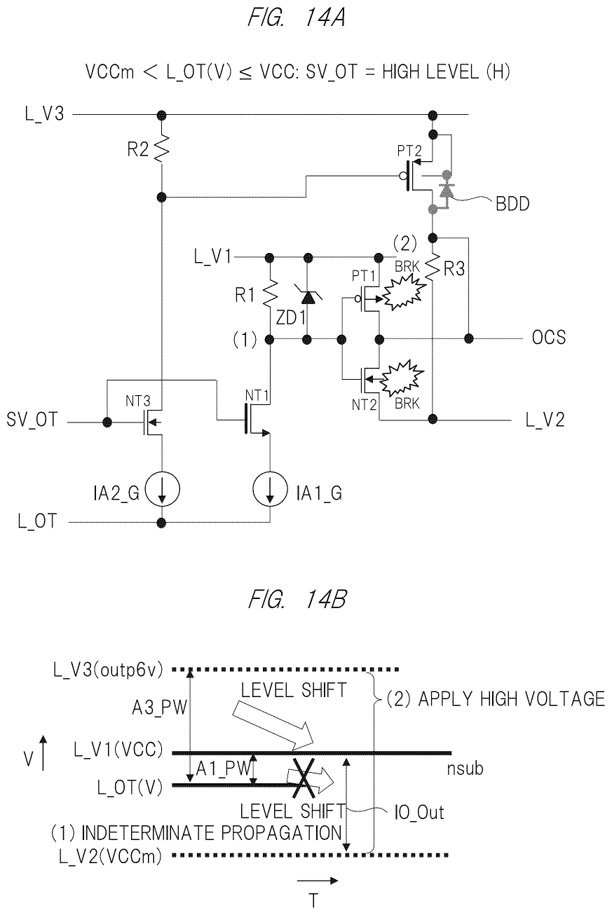

However, in Comparative Example 3, it has been found that new problems (1) to (6) to be described below arise. The new problems (1) to (6) will be described with reference to FIGS. 14A to 16B. FIGS. 14A to 16B are diagrams for describing the problems of Comparative Example 3.

FIGS. 14A and 14B are diagrams for describing the problems (1) and (2). Here, FIG. 14A is similar to FIG. 12B, and FIG. 14B is similar to FIG. 13A. A main difference is that the problems (1) and (2) are clearly illustrated in FIGS. 14A and 14B.

Problem (1): In a case where the voltage L_OT(V) of the output wiring L_OT is approximate to the voltage VCC, as illustrated in FIG. 14B, the power source voltage A1_PW of the amplifier circuit A1 (FIG. 12A) including the resistor R1, the N-type transistor NT1, and the current source IA1_G is reduced, and thus there is a concern that the output of the amplifier circuit A1 becomes indeterminate, and the output of the amplifier circuit A2 including the N-type transistor NT2 and the P-type transistor PT1 also becomes indeterminate. When the output of the amplifier circuit A2 becomes indeterminate, it is regarded that a high-level output signal from the amplifier circuit A4 including the P-type transistor PT2 and the resistor R3 is interrupted by the indeterminate output from the amplifier circuit A2 and becomes indeterminate, and it is regarded that indeterminate outputs are propagated.

Problem (2): The voltage L_V3(outp6v) higher than the voltage VCC is applied to the N-type transistor NT2 and the P-type transistor PT1 via the P-type transistor PT2. It is regarded that the N-type transistor NT2 and/or the P-type transistor PT1 is brought into a breakdown BRK with the high voltage L_V3(outp6v).

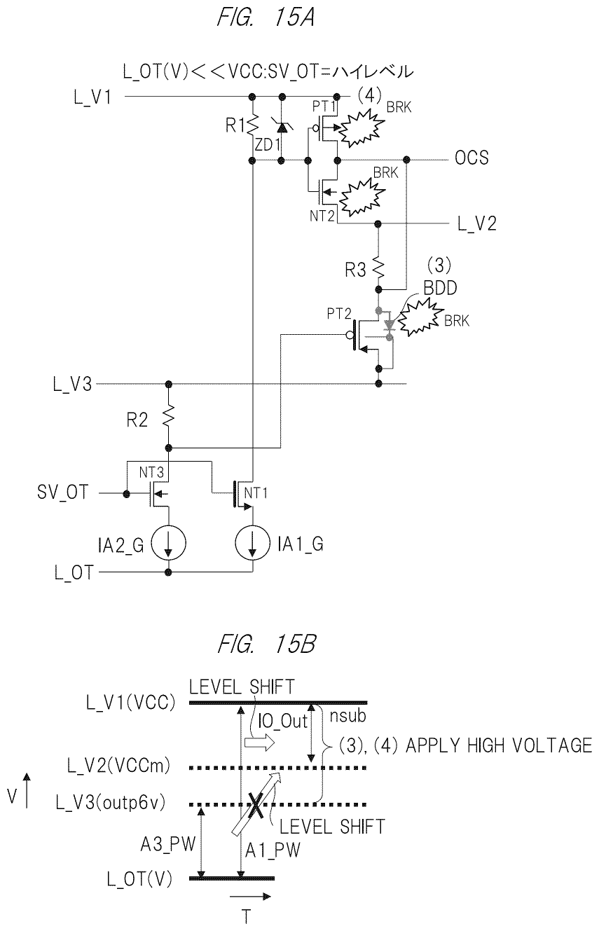

FIGS. 15A and 15B are diagrams for describing the problems (3) and (4). Here, FIG. 15A is similar to FIG. 12B, and FIG. 15B is similar to FIG. 13B. A main difference is that the problems (3) and (4) are clearly illustrated in FIGS. 15A and 15B. In addition, in FIG. 15A, circuit connection between elements is the same as that in FIG. 12B, but in this case, arrangement of the elements is changed so that the wirings having a high voltage are located on an upper side of the paper surface. Namely, in FIG. 15A, the wirings L_V1, L_V2, L_V3, and L_OT are arranged from the upper side to a lower side of the paper surface in the order of the voltages L_V1(VCC), L_V2(VCCm), L_V3(outp6v), and L_OT(V) illustrated in FIG. 15B.

Problem (3): Since the sense output signal SV_OT is set to the high level, it is regarded that the voltage L_V1(VCC) is scheduled to be output as the detection signal OCS via the P-type transistor PT1 but is not transmitted. This is because, in a case where on-resistance of the P-type transistor PT2 is high, the body diode BDD of the P-type transistor PT2 is considered as a load of the P-type transistor PT1, and it is regarded that the high-level detection signal OCS is transmitted to the third voltage wiring L_V3 via the body diode BDD. In this case, since the body diode BDD is connected to the voltage VCC via the P-type transistor PT1, it is also regarded that the breakdown BRK occurs.

Problem (4): The voltage L_V3(outp6v) lower than the voltage L_V2(VCCm) is applied to the drains of the P-type transistor PT1 and the N-type transistor NT2 via the body diode BDD of the P-type transistor PT2, for example. Namely, the voltage lower than the normally applied voltage VCCm is applied to the drains of the P-type transistor PT1 and the N-type transistor NT2, and it is regarded that the P-type transistor PT1 and/or the N-type transistor NT2 is brought into the breakdown BRK.

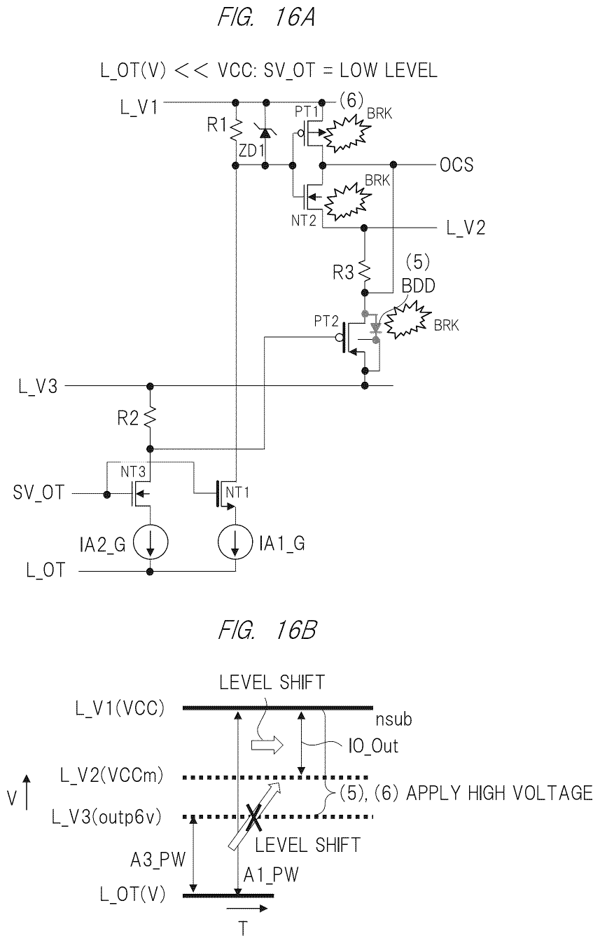

FIGS. 16A and 16B are diagrams for describing the problems (5) and (6). Here, FIG. 16A is similar to FIG. 15A, and FIG. 16B is similar to FIG. 15B. A main difference is that FIGS. 16A and 16B illustrate a state when the sense output signal SV_OT is set to the low level and further clearly illustrate the problems (5) and (6).

Problem (5): Since the sense output signal SV_OT is set to the low level, the voltage L_V2(VCCm) is scheduled to be output as the detection signal OCS via the N-type transistor NT2, but it is regarded that transmission thereof is not performed. This is because the body diode BDD of the P-type transistor PT2 is considered as a load of the N-type transistor NT2, and it is regarded that the detection signal OCS at the low level (Vccm) is transmitted to the third voltage wiring L_V3 via the body diode BDD. In addition, since the voltage L_V2(VCCm) is applied to the body diode BDD, it is also regarded that the body diode BDD is brought into the breakdown BRK.

Problem (6): The voltage L_V3(outp6v) lower than the voltage L_V2(VCCm) is applied to the drains of the P-type transistor PT1 and the N-type transistor NT2 via the body diode BDD, for example. Namely, a voltage lower than the normally applied voltage VCCm is applied to the drains of the P-type transistor PT1 and the N-type transistor NT2, and it is regarded that the P-type transistor PT1 and/or the N-type transistor NT2 is brought into the breakdown BRK.

As described above, since Comparative Example 3 also has the problems, the present inventor further studied and realized a semiconductor device including each overcurrent detection circuit according to each embodiment to be described below. As will be described in detail below, in the embodiments, the two signal paths PS1 and PS2 employed in Comparative Example 3 are improved and employed.

### First Embodiment

### Semiconductor Device

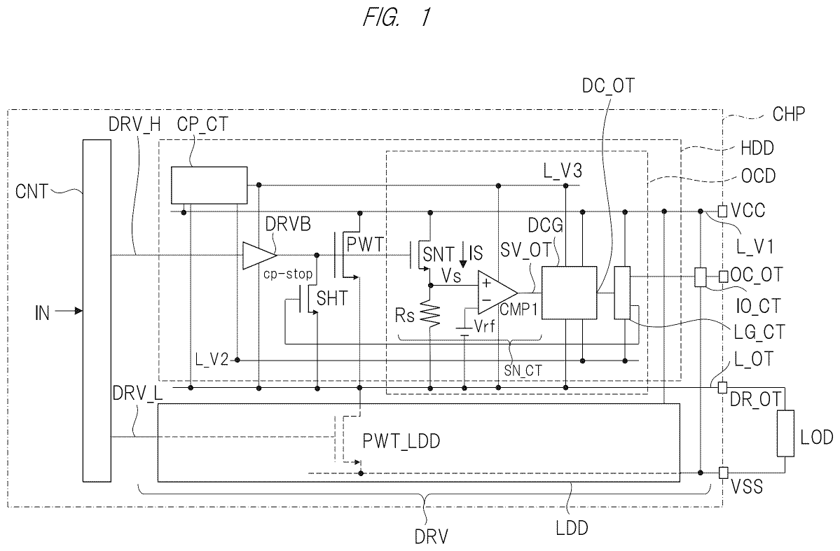

FIG. 1 is a block diagram illustrating a configuration of a semiconductor device according to a first embodiment. In FIG. 1, a semiconductor device CHP illustrated by a dash-dotted line includes a semiconductor chip, a package that seals the semiconductor chip, and an external terminal projecting from the package.

Although the semiconductor device CHP includes a large number of external terminals, only the external terminals necessary for the description are drawn on the dash-dotted line in FIG. 1. In FIG. 1, VCC represents a power supplying external terminal, and VSS represents a grounding external terminal. In addition, in FIG. 1, OC_OT represents a detection outputting external terminal (hereinafter also referred to as a detection output terminal), and DR_OT represents an outputting external terminal (hereinafter also simply referred to as an output terminal). These external terminals are electrically connected to a circuit block formed in the semiconductor chip in the package. In addition, in FIG. 1, LOD represents a load connected between the output terminal DR_OT and the grounding external terminal VSS.

Although a plurality of circuit blocks are formed in the semiconductor chip, only a circuit block necessary for the description is illustrated in FIG. 1. FIG. 1 illustrates a drive circuit DRV and a control circuit CNT as a circuit block. The control circuit CNT generates a high-side drive signal DRV_H and a low-side drive signal DRV_L in response to an input signal IN and supplies the high-side drive signal DRV_H and the low-side drive signal DRV_L to the drive circuit DRV. The drive circuit DRV includes a high-side drive circuit HDD, a low-side drive circuit LDD, and an input/output circuit IO_CT.

The high-side drive circuit HDD is connected to the power supplying external terminal VCC and the output terminal DR_OT. In addition, the high-side drive circuit HDD is connected to the detection output terminal OC_OT via the input/output circuit IO_CT. The high-side drive circuit HDD generates a drive signal in response to the high-side drive signal DRV_H and supplies the drive signal to the output terminal DR_OT. In addition, the low-side drive circuit LDD is connected to the power supplying external terminal VCC, the output terminal DR_OT, and the grounding external terminal VSS. The low-side drive circuit LDD generates a drive signal in response to the low-side drive signal DRV_L and supplies the drive signal to the output terminal DR_OT. The drive signal generated by the high-side drive circuit HDD and the drive signal generated by the low-side drive circuit LDD are combined at the output terminal DR_OT and supplied to a load LOD. This causes the load LOD to be driven based on the input signal IN.

### High-Side Drive Circuit

Next, a configuration of the high-side drive circuit HDD will be described. The high-side drive circuit HDD includes the charge pump circuit CP_CT which is a booster circuit, the driving buffer DRVB, the N-type transistor PWT which is a power device, the shutdown N-type transistor SHT, and the overcurrent detection circuit OCD.

The charge pump circuit CP_CT is connected to the first voltage wiring L_V1, the second voltage wiring L_V2, the third voltage wiring L_V3, and the output wiring L_OT. The first voltage wiring L_V1 is connected to the power supplying external terminal VCC, and the power source voltage (the first voltage) VCC is supplied via this external terminal from the outside of the semiconductor device CHP to the first voltage wiring L_V1. In addition, the output wiring L_OT is connected to the output terminal DR_OT.

The voltage (the second voltage) VCCm having a value lower than that of the voltage VCC is supplied to the second voltage wiring L_V2. This voltage VCCm is not particularly limited and is generated from the voltage VCC by a step-down circuit (not illustrated) in the semiconductor device CHP. The value of the voltage VCCm is not particularly limited and is a voltage VCC −6 V.

The charge pump circuit CP_CT generates a voltage having a predetermined value (for example, 6 V) based on the voltage VCC supplied via the first voltage wiring L_V1 and the voltage VCCm supplied via the second voltage wiring L_V2, adds (superimposes) this voltage to the voltage of the output wiring L_OT at that time, and supplies power to the third voltage wiring L_V3. Namely, a voltage obtained by the voltage of the output wiring L_OT+6 V (hereinafter also referred to as a voltage outp6v or a boosted voltage, similarly to <Comparative Examples>) is supplied to the third voltage wiring L_V3 from the charge pump circuit CP_CT.

The driving buffer DRVB is connected to the third voltage wiring L_V3 and the output wiring L_OT and operates with the voltage outp6v of the third voltage wiring L_V3 and the voltage in the output wiring L_OT as the power source voltages. This operation allows the driving buffer DRVB to buffer and output the high-side drive signal DRV_H from the control circuit CNT.

The drain of the N-type transistor PWT is connected to the first voltage wiring L_V1, and the source thereof is connected to the output wiring L_OT. Namely, the drain-source path of the N-type transistor PWT is connected in series between the first voltage wiring L_V1 and the output wiring L_OT. In addition, the gate of the N-type transistor PWT is connected to an output terminal of the driving buffer DRVB.

The drain of the shutdown N-type transistor SHT is connected to the output terminal of the driving buffer DRVB, and the source thereof is connected to the output wiring L_OT.

The overcurrent detection circuit OCD is connected to the first voltage wiring L_V1, the second voltage wiring L_V2, the third voltage wiring L_V3, the output wiring L_OT, the output terminal of the driving buffer DRVB, and the gate of the shutdown N-type transistor SHT. Further, the overcurrent detection circuit OCD is connected to the detection output terminal OC_OT via the input/output circuit IO_CT.

As will be described in detail below, the overcurrent detection circuit OCD senses a current (a drain-source current) flowing in the N-type transistor PWT based on an output of the driving buffer DRVB, supplies a detection signal indicating overcurrent to the input/output circuit IO_CT when the overcurrent occurs in the N-type transistor PWT, and makes the shutdown N-type transistor SHT be brought into the conductive state in response to the operation control signal cp-stop. This makes it possible to prevent the N-type transistor PWT from being brought into the breakdown due to the overcurrent.

The input/output circuit IO_CT is connected to the first voltage wiring L_V1 and the grounding external terminal VSS and operates with the voltage VCC of the first voltage wiring L_V1 and the voltage (the ground voltage) VSS in the grounding external terminal VSS as the power source voltages. This operation causes the input/output circuit IO_CT to convert the detection signal from the overcurrent detection circuit OCD into a detection signal that changes between the voltage VCC and the ground voltage VSS. The converted detection signal is output from the detection output terminal OC_OT to the outside of the semiconductor device CHP.

### Overcurrent Detection Circuit

The overcurrent detection circuit OCD includes a sense circuit SN_CT, a detection current generation circuit DCG, and the logic circuit (an output circuit) LG_CT.

The sense circuit SN_CT includes the N-type transistor SNT which is a sense device, a sense resistor Rs, the first comparison circuit CMP1, and the reference voltage Vrf. Here, the drain of the N-type transistor SNT is connected to the first voltage wiring L_V1, and the source thereof is connected to the output wiring L_OT via the sense resistor Rs. A positive input (sign +) of the first comparison circuit CMP1 is connected to a connection node connecting the source of the N-type transistor SNT and the sense resistor Rs, and a negative input (−) thereof is connected to the output wiring L_OT via the reference voltage Vrf. In addition, the first comparison circuit CMP1 is connected to the third voltage wiring L_V3 and the output wiring L_OT and performs, with the voltage outp6v of the third voltage wiring L_V3 and the voltage of the output wiring L_OT as power source voltages, comparison operation between the sense voltage Vs at the positive input (+) and the reference voltage Vrf at the negative input (−).

Here, the size of the N-type transistor SNT is 1 /K1 with respect to the size of the N-type transistor PWT, similarly to that described in FIG. 9. This indicates that, when both the N-type transistors PWT and SNT are brought into the conductive state by the driving buffer DRVB, the current (the sense current) Is flowing in the drain-source path of the N-type transistor SNT is proportional to a drain-source current flowing in the drain-source path of the N-type transistor PWT and has a small value that is 1 /K1 times a value of the drain-source current of the N-type transistor PWT. The first comparison circuit CMP1 compares the sense voltage Vs generated in the sense resistor Rs due to the sense current Is with the reference voltage Vrf. The first comparison circuit CMP1 outputs, as the sense output signal SV_OT which changes between the voltage outp6v of the third voltage wiring L_V3 and the voltage of the output wiring L_OT, the comparison result to the detection current generation circuit DCG.

The detection current generation circuit DCG is connected to the first voltage wiring L_V1, the second voltage wiring L_V2, the third voltage wiring L_V3, and the output wiring L_OT and operates with the voltages in these wirings as the power source voltages. This operation causes the detection current generation circuit DCG to output, from a detection output node DC_OT, a current in response to the sense output signal SV_OT supplied from the sense circuit SN_CT. The detection current generation circuit DCG will be described in detail below with reference to the drawings and, thus, is not further described here.

The logic circuit LG_CT is connected to the first voltage wiring L_V1 and the second voltage wiring L_V2 and operates with the voltage VCC of the first voltage wiring L_V1 and the voltage VCCm of the second voltage wiring L_V2 as the power source voltages. This operation causes the logic circuit LG_CT to generate a detection signal having a voltage value according to a value of a current output from a detection output node and the operation control signal cp-stop. Note that the detection signal generated here is a signal that changes between the voltage VCC and the voltage VCCm.

### Low-Side Drive Circuit

Similarly to the high-side drive circuit HDD, the low-side drive circuit LDD also includes a power device and an overcurrent detection circuit; however, in FIG. 1, only an N-type transistor PWT_LDD which is a power device is illustrated by a broken line. A drain of the N-type transistor PWT_LDD is connected to the output wiring L_OT, and a source thereof is connected to the grounding external terminal VSS via a voltage wiring illustrated by a broken line. In addition, the low-side drive signal DRV_L is supplied to the gate of the N-type transistor PWT_LDD.

The control circuit CNT is not particularly limited and sets the high-side drive signal DRV_H and the low-side drive signal DRV_L to the high level complementarily in response to the input signal IN. This causes the ground voltage VSS to be supplied to the output wiring L_OT and the output terminal DR_OT via the N-type transistor PWT_LDD in the conductive state when the low-side drive signal DRV_L is set to the high level. On the other hand, when the high-side drive signal DRV_H is set to the high level, the voltage VCC is supplied to the output wiring L_OT and the output terminal DR_OT via the N-type transistor PWT in the conductive state. As a result, the voltages of the output wiring L_OT and the output terminal DR_OT change between the voltage VCC and the ground voltage VSS in response to the input signal IN.

### Detection Current Generation Circuit

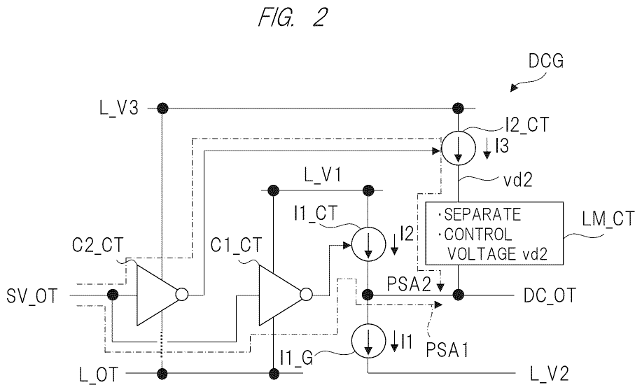

Next, a detection current generation circuit according to the first embodiment will be described with reference to the drawings. FIG. 2 is a block diagram illustrating a configuration of the detection current generation circuit according to the first embodiment. The detection current generation circuit DCG includes a first control circuit C1_CT, a second control circuit C2_CT, a first current circuit I1_CT, a second current circuit I2_CT, a first current source I1_G, and a voltage limiting circuit (hereinafter also simply referred to as a limiting circuit) LM_CT.

The first control circuit C1_CT is connected to the first voltage wiring L_V1 and the output wiring L_OT and operates with the voltage VCC of the first voltage wiring L_V1 and the voltage in the output wiring L_OT as the power source voltages. This operation causes the first control circuit C1_CT to output, to the first current circuit I1_CT, a signal in response to the sense output signal SV_OT from the sense circuit SN_CT. A signal output from the first control circuit C1_CT is a voltage signal that changes between the voltage VCC and the voltage in the output wiring L_OT. The first current circuit I1_CT is connected between the first voltage wiring L_V1 and the detection output node DC_OT of the detection current generation circuit DCG and supplies a current (a second current) I2 having a predetermined value to the detection output node DC_OT in response to the voltage signal from the first control circuit C1_CT.

The second control circuit C2_CT is connected to the third voltage wiring L_V3 and the output wiring L_OT and operates with the voltage outp6v of the third voltage wiring L_V3 and the voltage in the output wiring L_OT as the power source voltages. This operation causes the second control circuit C2_CT to output, to the second current circuit I2_CT, a signal in response to the sense output signal SV_OT. A signal output from the second control circuit C2_CT is a voltage signal that changes between the voltage outp6v and the voltage in the output wiring L_OT. The second current circuit I2_CT is connected between the third voltage wiring L_V3 and the limiting circuit LM_CT and supplies a current (a third current) I3 having a predetermined value toward the limiting circuit LM_CT in response to the voltage signal from the second control circuit C2_CT.

The first current source I1_G is connected between the detection output node DC_OT and the second voltage wiring L_V2. The first current source I1_G supplies the current (the first current) I1 having a predetermined value smaller than the second and third currents I2 and I3 from the detection output node DC_OT toward the second voltage wiring L_V2. A value of the second current I2 and a value of the third current I3 may be equal to or different from each other, but each value of the second current I2 and the third current I3 is larger than the value of the first current I1 (I2 and I3>I1).

The limiting circuit LM_CT is connected between the second current circuit I2_CT and the detection output node DC_OT. The limiting circuit LM_CT limits a voltage at the detection output node DC_OT so as not to be equal to or higher than the voltage VCC of the first voltage wiring L_V1 and so as not to be equal to or lower than the voltage VCCm of the second voltage wiring L_V2.

In FIG. 2, it can be considered that an improved signal path PSA1 includes the first control circuit C1_CT and the first current circuit I1_CT, and an improved signal path PSA2 includes the second control circuit C2_CT, the second current circuit I2_CT, and the limiting circuit LM_CT. Through the signal path PSA1, the second current I2 is supplied to the detection output node DC_OT in response to a voltage of the sense output signal SV_OT. In addition, through the signal path PSA2, the third current I3 is supplied to the detection output node DC_OT in response to a voltage of the sense output signal SV_OT. At the detection output node DC_OT, the second current I2, the third current I3, and the first current I1 are combined (I2+I3−I1), and a result of the combination is output from the detection output node DC_OT. Since both the values of the second current I2 and the third current I3 are larger than the value of the first current I1, a value of the combined currents (I2+I3) can become larger than the first current I1 without depending on the voltage in the output wiring L_OT. Hence, it is possible to output a current corresponding to the high level from the detection output node DC_OT.

In addition, since a voltage of the detection output node DC_OT is limited by the limiting circuit LM_CT, it is possible to prevent a circuit connected to the detection output node DC_OT and the second current circuit I2_CT from being brought into the breakdown due to the high voltage.

Note that, in FIG. 2, reference sign vd2 represents a voltage at a connection node connecting the second current circuit I2_CT and the limiting circuit LM_CT.

### Example of Detection Current Generation Circuit

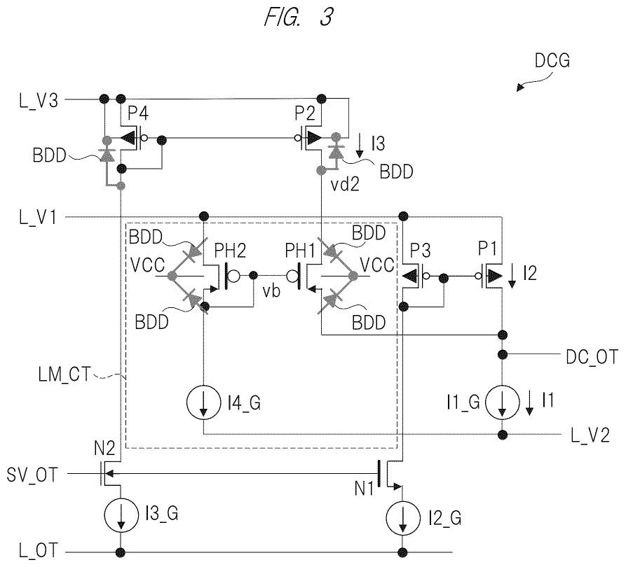

Next, a specific example of the detection current generation circuit DCG described with reference to FIG. 2 will be described with reference to the drawings. FIG. 3 is a circuit diagram illustrating a configuration of the detection current generation circuit according to the first embodiment.

The detection current generation circuit DCG includes N-type transistors N1 and N2, P-type transistors P1 to P4, PH1, and PH2, and current sources (first to fourth current sources) I1_G to I4_G.

A corresponding relationship between the block diagram of FIG. 2 and the circuit diagram of FIG. 3 is as follows. The first control circuit C1_CT illustrated in FIG. 2 includes the second current source I2_G, the N-type transistor N1, and the P-type transistor P3, and the second control circuit C2_CT includes the third current source I3_G, the N-type transistor N2, and the P-type transistor P4. In addition, the first current circuit I1_CT includes the P-type transistor P1, and the second current circuit I2_CT includes the P-type transistor P2. Further, the limiting circuit LM_CT includes the fourth current source I4_G and the P-type transistors PH1 and PH2.

A drain-source path of the P-type transistor P3, a drain-source path of the N-type transistor N1, and the second current source I2_G are connected in series between the first voltage wiring L_V1 and the output wiring L_OT. The drain-source path of the P-type transistor P1 is connected between the first voltage wiring L_V1 and the detection output node DC_OT. A gate of the P-type transistor P1 is connected to a gate of the P-type transistor P3 and a drain of the P-type transistor P3 so that the P-type transistor P1 and the P-type transistor P3 constitute a current mirror circuit. In addition, the sense output signal SV_OT is supplied to a gate of the N-type transistor N1.

A drain-source path of the P-type transistor P4, a drain-source path of the N-type transistor N2, and the third current source I3_G are connected in series between the third voltage wiring L_V3 and the output wiring L_OT. A drain-source path of the P-type transistor P2 is connected between the third voltage wiring L_V3 and the limiting circuit LM_CT. A gate of the P-type transistor P2 is connected to a gate of the P-type transistor P4 and a drain of the P-type transistor P4 so that the P-type transistor P2 and the P-type transistor P4 constitute a current mirror circuit. In addition, the sense output signal SV_OT is supplied to a gate of the N-type transistor N2.

A drain of the P-type transistor PH1 is connected to the P-type transistor P2, and a source thereof is connected to the detection output node DC_OT. In addition, a drain of the P-type transistor PH2 is connected to the first voltage wiring L_V1, and a source thereof is connected to the detection output node DC_OT via the fourth current source I4_G. A gate of the P-type transistor PH2 is connected to the source of the P-type transistor PH2 and a gate of the P-type transistor PH1. The source and the gate of the P-type transistor PH2 are connected to each other, thereby applying, to the gates of the P-type transistors PH1 and PH2, a bias voltage vb having a value (a VCC-threshold voltage) obtained by subtracting a threshold voltage of the P-type transistor PH2 from the voltage VCC. Note that, since the threshold voltage of the P-type transistor PH2 and a threshold voltage of the P-type transistor PH1 have substantially the same value, a value of the bias voltage vb can be regarded as a value obtained by subtracting the threshold voltage of the P-type transistor PH1 from the voltage VCC.

Back gates of the P-type transistors PH1 and PH2 are connected to the voltage VCC of the first voltage wiring L_V1. This indicates that, as illustrated in FIG. 3, the body diodes BDD are formed between the sources and the back gates of the P-type transistors PH1 and PH2 and between the drains and the back gates of the P-type transistors PH1 and PH2.

Note that, as illustrated in FIG. 3, since back gates of the P-type transistors P2 and P4 are connected to the third voltage wiring L_V3, the body diodes BDD are also formed between the drains and the back gates of the P-type transistors P2 and P4.

In FIG. 3, the transistors having the gates illustrated as thick lines, that is, the P-type transistors PH1 and PH2 and the N-type transistor N1, have a structure in which withstand voltages between the drains and the gates and withstand voltages of the gates are increased. For example, the withstand voltages between the drains and the gates of the P-type transistors PH1 and PH2 and the N-type transistor N1 are higher than withstand voltages between the sources and the gates of the P-type transistors PH1 and PH2 and the N-type transistor N1 and are higher than withstand voltages between the sources and gates and between the drains and gates of the P-type transistors P1 to P4 and the N-type transistor N2. In addition, withstand voltages of the gates of the P-type transistors PH1 and PH2 and the N-type transistor N1 are higher than gate withstand voltages of the P-type transistors P1 to P4 and the N-type transistor N2.

### Structure of P-Type Transistors PH1 and PH2

A structure of a transistor having a withstand voltage between a drain and a gate which is higher than a withstand voltage between a source and a gate will be described with the P-type transistor PH1 as an example with reference to the drawings. Here, a case where the P-type transistor PH1 having a high withstand voltage is manufactured in a manufacturing process that enables manufacturing costs to be reduced will be described.

FIG. 4 is a cross-sectional view illustrating a cross section of a semiconductor chip according to the first embodiment. FIG. 4 illustrates a cross section of the P-type transistor (a fifth P-type transistor) PH1. As a matter of course, the P-type transistor (a sixth P-type transistor) PH2 is also formed in the same manner as PH1.

In FIG. 4, nsub represents an N-type semiconductor substrate which is a substrate of a semiconductor chip. The N-type semiconductor substrate nsub is not particularly limited and is connected to the first voltage wiring L_V1 so that the voltage VCC is applied thereto. Note that reference sign nsub illustrated in the drawings of the comparative examples (for example, FIG. 10B) represents a voltage of the N-type semiconductor substrate.

A plurality of transistors such as the P-type and N-type transistors illustrated in FIGS. 1 and 2 are formed on the N-type semiconductor substrate nsub. Among these transistors, only a region in which the P-type transistor PH1 is formed is illustrated in FIG. 4.

In a region in which the P-type transistor PH1 is formed, a P-type well pwell and an N-type well nwell formed to surround the P-type well pwell when viewed in plan view are formed. In the N-type well nwell, an N-type semiconductor region N+constituting a back gate BG of the P-type transistor PH1 is formed. In addition, in the N-type well nwell, a P-type semiconductor region P+separated from the N-type semiconductor region N+by an isolation layer ISO is formed. The P-type semiconductor region P+constitutes a source S of the P-type transistor PH1. Further, the N-type semiconductor region N+constituting a drain D of the P-type transistor PH1 is formed in the N-type well nwell. In FIG. 4, G represents a gate electrode (a gate) formed on an N-type well nwell via an insulating film (not illustrated).

In the semiconductor device CHP according to the first embodiment, as illustrated in FIG. 4, a distance DLL between the gate electrode G and the P-type semiconductor region (a drain region) P+constituting the drain D becomes longer than a distance SLL between the gate electrode G and the P-type semiconductor region (a source region) P+constituting the source S. This indicates that, in the P-type transistor PH1, the withstand voltage between the drain and the gate is set higher than the withstand voltage between the source and the gate.

In addition, as illustrated in FIG. 4, the N-type well nwell to which the back gate BG is connected is formed without being separated from the N-type semiconductor substrate nsub by the isolation layer. Therefore, it is possible to reduce the manufacturing cost related to the formation of the isolation layer. However, in such a structure, it is difficult to apply, to the back gate BG, a voltage other than the voltage VCC having the same potential as the N-type semiconductor substrate nsub, and the voltage VCC is supplied as described with reference to FIG. 3.

### Operation of Detection Current Generation Circuit

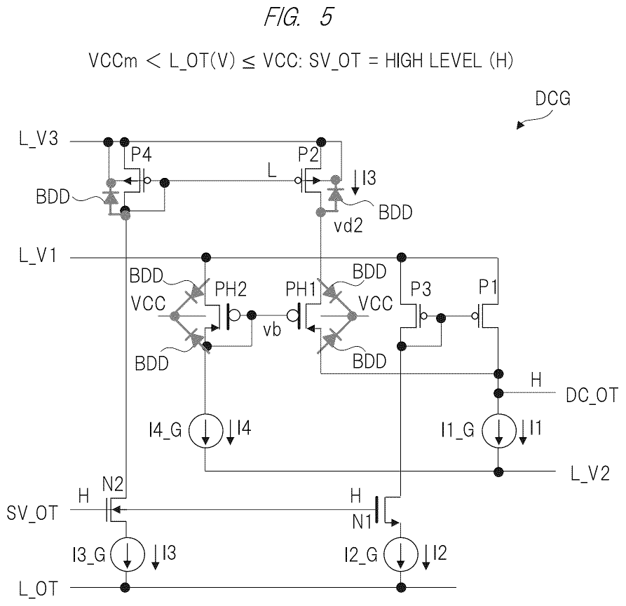

Next, operation of the detection current generation circuit according to the first embodiment will be described with reference to the drawings. Here, the detection current generation circuit will be described with reference to the drawings corresponding to FIGS. 14A to 16B used for describing the problems in Comparative Example 3. FIGS. 5 to 7 are diagrams for describing the operation of the detection current generation circuit according to the first embodiment.

<<<<VCCm<L_OT(V)≤VCC: SV_OT=High Level>>>>

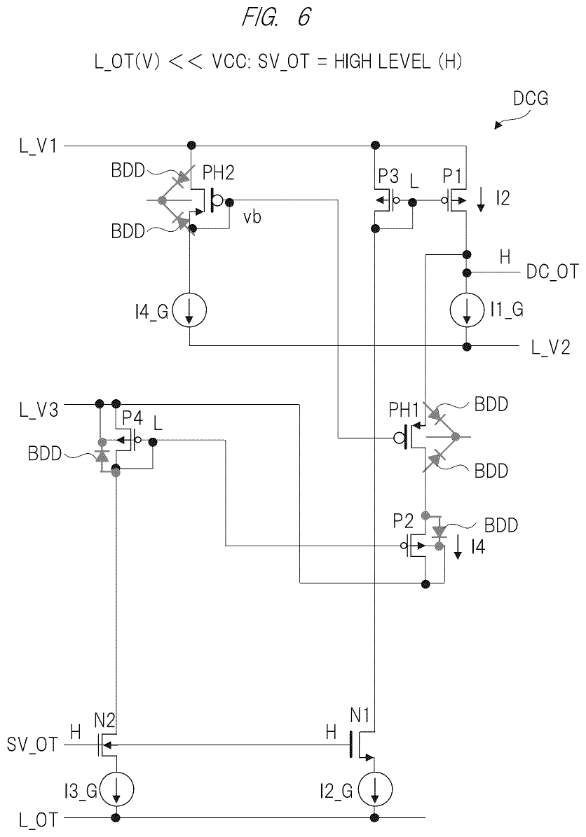

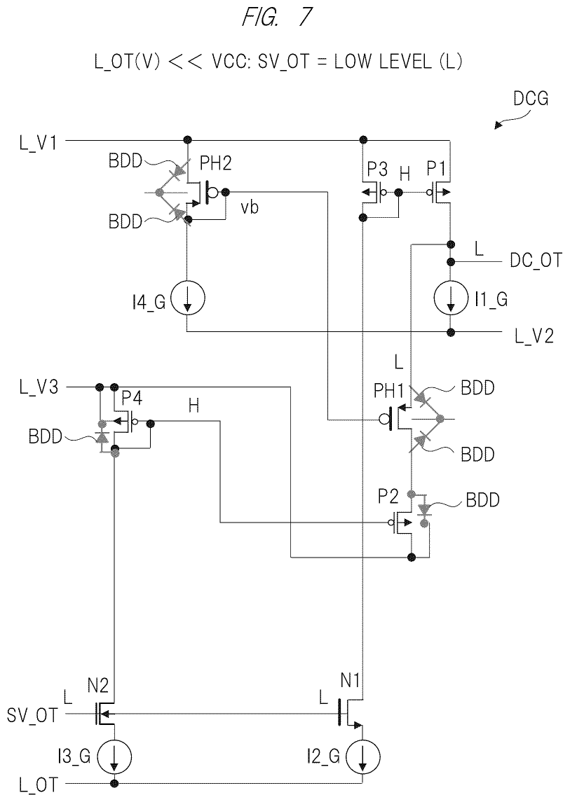

Similarly to FIGS. 14A and 14B, FIG. 5 illustrates a case where the sense output signal SV_OT is set to the high level (H) in a state in which the voltage L_OT(V) of the output wiring L_OT is higher than the voltage VCCm of the second voltage wiring L_V2 and is equal to or lower than the voltage VCC of the first voltage wiring L_V1. FIG. 5 illustrates, for example, a case where the sense voltage Vs becomes higher than the reference voltage Vrf, and the overcurrent is detected, in a state in which the N-type transistor PWT illustrated in FIG. 1 is brought into the conductive state, and the voltage of the output wiring L_OT is approximate to the voltage VCC by the N-type transistor PWT. In addition, reference signs H and L illustrated in FIG. 5 represent a high level and a low level, respectively. Reference signs H and L have the same meanings in FIGS. 6 and 7 to be described below. Since the voltage L_OT(V) of the output wiring L_OT is approximate to the voltage VCC, the voltage outp6v of the third voltage wiring L_V3 is higher than the voltage VCC of the first voltage wiring L_V1.

Since the sense output signal SV_OT is set to the high level (H), the N-type transistor N2 is brought into the conductive state. This causes the low level (L) to be supplied to the gates of the P-type transistors P2 and P4. Since the current mirror circuit includes the P-type transistors P2 and P4, the third current I3 corresponding to a current of the third current source I3_G is supplied from the third voltage wiring L_V3 to the P-type transistor PH1 via the N-type transistor N2 in the conductive state. Since the gate of the P-type transistor PH1 is biased with the bias voltage vb (=the voltage VCC−the threshold voltage of the P-type transistor PH2), the P-type transistor PH1 supplies the supplied third current I3 to the detection output node DC_OT. At this time, the voltage vd2 at a connection node connecting the drain of the P-type transistor PH1 and the P-type transistor P2 is limited to the voltage VCC. This is because the voltage vd2 is limited to a voltage obtained by adding a threshold voltage of the P-type transistor PH1 to the bias voltage vb, and the voltage vd2 is limited to the voltage VCC by the body diode BDD connected between the drain and the back gate of the P-type transistor PH1.

Since the voltage L_OT(V) of the output wiring L_OT is approximate to the voltage VCC, a potential difference applied to the P-type transistor P3, the N-type transistor N1, and the second current source I2_G which are series circuits connected in series between the output wiring L_OT and the first voltage wiring L_V1 approaches 0 V, for example, and the power source voltage of the series circuit collapses. Therefore, even when the sense output signal SV_OT of the high level (H) is supplied to the N-type transistor N1, a current flowing in the P-type transistor P3 is very low, or the P-type transistor P3 is brought into the non-conductive state. As a result, a current flowing in the P-type transistor P1 constituting, with the P-type transistor P3, the mirror circuit is also very low or is substantially 0 A. This can prevent an indeterminate signal from being transmitted to the detection output node DC_OT via the P-type transistor P1.

At this time, a current corresponding to a difference between the third current I3 from the P-type transistor PH1 and the first current I1 from the first current source I1_G is supplied to the detection output node DC_OT. Since the value of the third current I3 is larger than the value of the first current I1, the current of this difference corresponds to the high level (H).

In addition, the voltage vd2 at the connection node connecting the P-type transistor P2 and the drain of the P-type transistor PH1 is limited to the voltage VCC, and the detection output node DC_OT and the third voltage wiring L_V3 are separated. Therefore, it is possible to prevent a voltage equal to or higher than the voltage VCC from being applied to the detection output node DC_OT. Further, for example, even if noise is superimposed on the voltage vd2 of the connection node, and the voltage vd2 exceeds the voltage VCC, the voltage vd2 is clamped to the voltage VCC since the body diode BDD of the P-type transistor PH1 is connected between the connection node and the voltage VCC. This can prevent a transistor (for example, the P-type transistor P1 or PH1) and the first current source I1_G connected to the detection output node DC_OT from being brought into the breakdown due to the high voltage.

<<<<L_OT(V)<<VCC: SV_OT=High Level>>>>

Similarly to FIGS. 15A and 15B, FIG. 6 illustrates a case where the sense output signal SV_OT is set to the high level (H) in a state in which the voltage L_OT(V) of the output wiring L_OT becomes significantly lower than the voltage VCC of the first voltage wiring L_V1. FIG. 6 illustrates, for example, a case where the overcurrent is detected, in a state in which the N-type transistor PWT_LDD in the low-side drive circuit LDD illustrated in FIG. 1 is brought into the conductive state, and the voltage of the output wiring L_OT becomes significantly lower than the voltage VCC by the N-type transistor PWT_LDD and becomes approximate to the ground voltage VSS, for example.

In addition, similarly to FIG. 15A, in FIG. 6, circuit connection between elements is the same as that in FIG. 3, but in this case arrangement of the elements is changed so that the wirings having a high voltage are located on an upper side of the paper surface. Namely, in FIG. 6, the voltages decrease in the order of the voltage VCC of the first voltage wiring L_V1, the voltage VCCm of the second voltage wiring L_V2, the voltage outp6v of the third voltage wiring L_V3, and the voltage L_OT(V) of the output wiring L_OT.

Since the sense output signal SV_OT is set to the high level (H), the N-type transistor N2 is brought into the conductive state, and a current flows from the third voltage wiring L_V3 to the output wiring L_OT via the third current source I3_G, the N-type transistor N2, and the P-type transistor P4. This indicates that the voltages of the gates of the P-type transistors P4 and P2 are set to the low level (L), a current lower than the current I4 flowing in the fourth current source I4_G flows in the P-type transistor P2, and the voltage vd2 at the connection node connecting the P-type transistor P2 and the drain of the P-type transistor PH1 has a value approximate to the voltage outp6v of the third voltage wiring L_V3. At this time, since the bias voltage vb is supplied to the gate of the P-type transistor PH1, the P-type transistor PH1 is brought into the non-conductive state.

As a result, the connection node connecting the P-type transistor P2 and the drain of the P-type transistor PH1 and the detection output node DC_OT are separated, and the voltage outp6v of the third voltage wiring L_V3 is not supplied to the detection output node DC_OT. This can prevent a high voltage from being applied between the second voltage wiring L_V2 and the detection output node DC_OT and can prevent the first current source I1_G from being brought into the breakdown, for example.

In the state illustrated in FIG. 6, that is, in a state in which the voltage L_OT(V) of the output wiring L_OT becomes significantly lower than the voltage VCC of the first voltage wiring L_V1, a large potential difference is supplied to the series circuit including the P-type transistor P3, the N-type transistor N1, and the second current source I2_G which are connected in series between the first voltage wiring L_V1 and the output wiring L_OT. Therefore, the N-type transistor N1 is brought into the conductive state in response to the sense output signal SV_OT of the high level (H), and the P-type transistors P1 and P3 are also brought into the conductive state. As a result, the second current I2 proportional to the current of the second current source I2_G is supplied from the P-type transistor P1 toward the detection output node DC_OT, and a difference between the second current I2 and the first current I1 is output from the detection output node DC_OT. Since a value of the second current I2 is larger than the value of the first current I1, the current of this difference corresponds to the high level (H).

At this time, since the P-type transistor PH1 is brought into the non-conductive state, the body diode BDD of the P-type transistor P2 is separated from the detection output node DC_OT by the P-type transistor PH1. This indicates that the body diode BDD does not become a load of the P-type transistor P1 and the first current source I1_G.

<<<<L_OT(V)<<VCC: SV_OT=Low Level>>>>

Similarly to FIGS. 16A and 16B, FIG. 7 illustrates a case where the sense output signal SV_OT is set to the low level (L) in a state in which the voltage L_OT(V) of the output wiring L_OT becomes significantly lower than the voltage VCC of the first voltage wiring L_V1. FIG. 7 illustrates, for example, a case where the overcurrent is not detected, in a state in which the N-type transistor PWT_LDD in the low-side drive circuit LDD illustrated in FIG. 1 is brought into the conductive state, and the voltage of the output wiring L_OT becomes significantly lower than the voltage VCC by the N-type transistor PWT_LDD and becomes approximate to the ground voltage VSS, for example.

Here, FIG. 7 is similar to FIG. 6. A main difference is that, in FIG. 7, the sense output signal SV_OT is set to the low level (L). The N-type transistors N1 and N2 are brought into the non-conductive state in response to the sense output signal SV_OT of the low level (L).

The non-conductive state of the N-type transistor N2 causes the voltages of the gates of the P-type transistors P4 and P2 to have the high level (H). This indicates that the current flowing in the P-type transistor P2 becomes substantially 0 A; however, since the bias voltage vb is supplied to the gate of the P-type transistor PH1, the voltage vd2 of the connection node connecting the P-type transistor P2 and the drain of the P-type transistor PH1 becomes a value approximate to the voltage outp6v of the third voltage wiring L_V3, similarly to the case of FIG. 6. As a result, also in the case of FIG. 7, the P-type transistor PH1 is brought into the non-conductive state, and the detection output node DC_OT and the connection node connecting the P-type transistor P2 and the drain of the P-type transistor PH1 are separated by the P-type transistor PH1. This can prevent a high voltage from being applied between the second voltage wiring L_V2 and the detection output node DC_OT and can prevent the first current source I1_G from being brought into the breakdown, for example.

As described with reference to FIG. 6, also in the state illustrated in FIG. 7, a large potential difference is supplied to the series circuit including the P-type transistor P3, the N-type transistor N1, and the second current source I2_G which are connected in series between the first voltage wiring L_V1 and the output wiring L_OT. Therefore, the N-type transistor N1 is brought into the non-conductive state in response to the sense output signal SV_OT of the low level (L), and the P-type transistors P1 and P3 are also brought into the non-conductive state. As a result, the current supplied from the P-type transistor P1 toward the detection output node DC_OT becomes substantially 0 A, a difference between the first current I1 and the second current I2 becomes only the first current I1, and the first current I1 corresponding to the low level (L) is output from the detection output node DC_OT.

At this time, also in FIG. 7, since the P-type transistor PH1 is brought into the non-conductive state, the body diode BDD of the P-type transistor P2 is separated from the detection output node DC_OT by the P-type transistor PH1. This indicates that the body diode BDD does not become a load of the first current source I1_G.

As illustrated in FIG. 5, in a case where the voltage L_OT(V) of the output wiring L_OT is approximate to the voltage VCC, the voltage outp6v of the third voltage wiring L_V3 becomes higher than the voltage VCC of the first voltage wiring L_V1. At this time, when the overcurrent is detected, as described with reference to FIG. 5, the voltage vd2 is controlled by the P-type transistors PH1 and PH2 constituting the limiting circuit LM_CT (FIG. 3), and the voltage vd2 is limited to a value approximate to the voltage VCC. This indicates that the voltage of the detection output node DC_OT is limited so as not to be equal to or higher than the voltage VCC of the first voltage wiring L_V1.

In addition, as illustrated in FIGS. 6 and 7, in the case of the state in which the voltage L_OT(V) of the output wiring L_OT becomes significantly lower than the voltage VCC, the voltage outp6v of the third voltage wiring L_V3 becomes lower than the voltage VCCm of the second voltage wiring L_V2. At this time, as described with reference to FIGS. 6 and 7, the P-type transistor PH1 constituting the limiting circuit LM_CT (FIG. 3) is brought into the non-conductive state. This causes the third voltage wiring L_V3 to be separated from the detection output node DC_OT, and the voltage of the detection output node DC_OT is limited so as not to be equal to or lower than the voltage VCCm of the second voltage wiring L_V2.

As described above, the voltage of the detection output node DC_OT is limited, whereby it is possible to prevent an element that supplies the first current I1 to the detection output node DC_OT and an element connected to the detection output node DC_OT from being brought into the breakdown.

### Second Embodiment

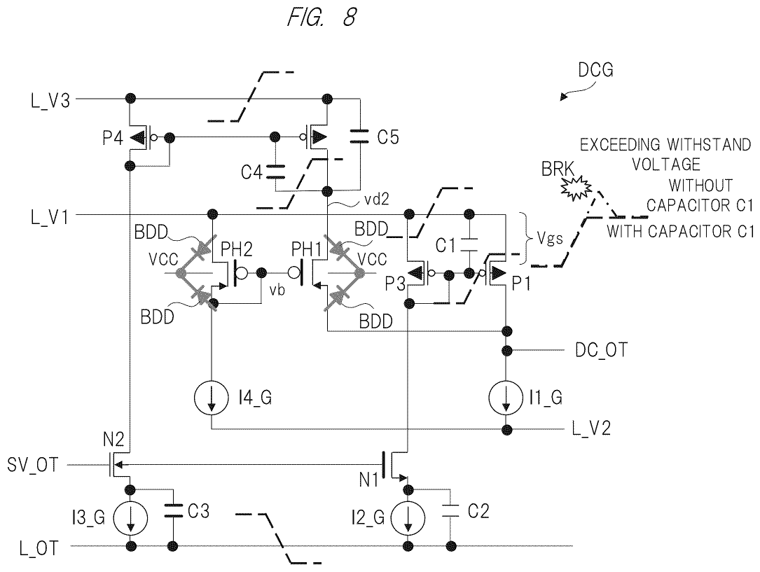

FIG. 8 is a circuit diagram illustrating a configuration of a detection current generation circuit according to a second embodiment. FIG. 8 is similar to FIG. 3. A main difference is that capacitors C1 to C5 are added to the detection current generation circuit DCG of FIG. 8. Specifically, the capacitor C1 is connected between the gate and the source of the P-type transistor P1, the capacitor C2 is connected to the second current source I2_G in parallel, and the capacitor C3 is connected to the third current source I3_G in parallel. In addition, the capacitor C4 is connected between the gate of the P-type transistor P2 and the connection node connecting the P-type transistor P2 and the drain of the P-type transistor PH2, and the capacitor C5 is connected between the drain and the source of the P-type transistor P2.

When the voltage of the output wiring L_OT and/or the voltage of the sense output signal SV_OT changes, voltages of elements and wirings may change steeply, overshoot and/or undershoot may occur, the voltages may exceed the withstand voltages of the elements, and the breakdown may occur.

In the second embodiment, by adding the capacitors C1 to C5, the occurrence of the overshoot and/or the undershoot is reduced, and it is possible to prevent the elements from being brought into the breakdown. FIG. 8 illustrates, as an example, a change in gate-source voltage Vgs of the P-type transistor P2. In a case where no capacitor C1 is provided, as illustrated by a dash-dotted line, the overshoot occurs and brings about the breakdown BRK. On the other hand, in a case where the capacitor C1 is added, as illustrated by a broken line, it is possible to reduce the occurrence of the overshoot and to prevent the breakdown BRK.

Also at locations at which the capacitors C2 to C5 are connected, similarly to a location at which the capacitor C1 is connected, as illustrated by a broken line, it is possible to reduce the occurrence of the overshoot and/or the undershoot and to prevent the element from being brought into the breakdown.

Although the invention made by the present inventor has been specifically described based on the embodiments, the present invention is not limited to the embodiments, and it goes without saying that various modifications can be made without departing from the gist of the invention.

What is claimed is:

1. A semiconductor device comprising:
a power device connected between a first voltage wiring and an output terminal;
a booster circuit that is connected to the first voltage wiring, a second voltage wiring different from the first voltage wiring, and the output terminal, generates a boosted voltage boosted with respect to a voltage in the output terminal, and supplies the boosted voltage to a third voltage wiring different from the first voltage wiring and the second voltage wiring; and
an overcurrent detection circuit connected to the first voltage wiring, the second voltage wiring, the third voltage wiring, and the output terminal,
wherein the overcurrent detection circuit includes:
a sense circuit that outputs a voltage corresponding to a current flowing in the power device;
a detection current generation circuit that generates a detection current depending on an output from the sense circuit; and
an output circuit that generates a detection signal based on the detection current generated by the detection current generation circuit, and
wherein the detection current generation circuit includes:
a first current source that is connected between a detection output node of the detection current generation circuit and the second voltage wiring and supplies a first current having a predetermined value to the second voltage wiring;
a first current circuit that is connected between the detection output node and the first voltage wiring and supplies a second current having a value larger than the predetermined value to the detection output node;
a second current circuit that is connected to the third voltage wiring and supplies a third current having a value larger than the predetermined value toward the detection output node;
a limiting circuit that is connected between the second current circuit and the detection output node and limits a voltage at the detection output node so as not to be equal to or higher than a first voltage in the first voltage wiring and so as not to be equal to or lower than a second voltage in the second voltage wiring;
a first control circuit that controls the first current circuit depending on a voltage output from the sense circuit, with the first voltage in the first voltage wiring and a voltage at the output terminal as power source voltages; and
a second control circuit that controls the second current circuit depending on a voltage output from the sense circuit, with a voltage in the third voltage wiring and a voltage in the output terminal as power source voltages.

2. The semiconductor device according to claim 1,
wherein the first current circuit includes a first P-type transistor having a drain-source path connected between the first voltage wiring and the detection output node,
wherein the second current circuit includes a second P-type transistor having a drain-source path connected between the third voltage wiring and the limiting circuit,
wherein the first control circuit includes a third P-type transistor, a first N-type transistor, and a second current source which are connected in series between the first voltage wiring and the output terminal, a voltage output from the sense circuit is supplied to a gate of the first N-type transistor, and a gate of the third P-type transistor is connected to a source of the third P-type transistor and a gate of the first P-type transistor,
wherein the second control circuit includes a fourth P-type transistor, a second N-type transistor, and a third current source which are connected in series between the third voltage wiring and the output terminal, a voltage output from the sense circuit is supplied to a gate of the second N-type transistor, and a gate of the fourth P-type transistor is connected to a source of the fourth P-type transistor and a gate of the second P-type transistor,
wherein the limiting circuit separates the second P-type transistor and the detection output node from each other when a voltage in the output terminal is a voltage significantly lower than the first voltage, and
wherein the limiting circuit limits, to the first voltage, a voltage of a connection node connecting the limiting circuit and the second P-type transistor when the voltage in the output terminal is a voltage between the second voltage and the first voltage.

3. The semiconductor device according to claim 2,
wherein the limiting circuit has a structure in which a drain-gate withstand voltage is higher than a source-gate withstand voltage, and includes a fifth P-type transistor including a drain connected to the second P-type transistor, a source connected to the detection output node, a back gate to which the first voltage is supplied, and a gate to which a bias voltage lower than the first voltage is supplied.

4. The semiconductor device according to claim 3,
wherein the limiting circuit includes, as a bias circuit that generates the bias voltage, a sixth P-type transistor and a fourth current source connected in series between the first voltage wiring and the second voltage wiring, and
wherein the sixth P-type transistor has a structure in which a drain-gate withstand voltage is higher than a source-gate withstand voltage, and includes a drain connected to the first voltage wiring, a source connected to the second voltage wiring via the fourth current source, a back gate to which the first voltage is supplied, and a gate connected to a source of the sixth P-type transistor and a gate of the fifth P-type transistor.

5. The semiconductor device according to claim 4,
wherein, in the fifth P-type transistor and the sixth P-type transistor, when viewed in cross-sectional view, a distance between a drain region constituting the drain and a gate electrode constituting the gate is longer than a distance between a source region constituting the source and the gate electrode constituting the gate.

6. The semiconductor device according to claim 5,
wherein the sense circuit includes a sense device in which a current proportional to the current flowing in the power device flows, a sense resistor, a comparison circuit, and a reference voltage,
wherein a drain-source path of the sense device and the sense resistor are connected in series between the first voltage wiring and the output terminal, and
wherein the comparison circuit is connected to the third voltage wiring and the output terminal and compares a voltage at the sense resistor with the reference voltage, with a voltage in the third voltage wiring and a voltage in the output terminal as power source voltages.
